(19) United States
(12) Patent Application Publication
(10) Pub. No.: US 2007/0110262 A1
(43) Pub. Date: May 17, 2007

(54) Apparatus and method to control volume of received sound signals

(75) Inventors: Young-joon Ahn, Suwon-si (KR); Jeong-hun Park, Yongin-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/595,860

(22) Filed: Nov. 13, 2006

(30) Foreign Application Priority Data
Nov. 17, 2005 (KR) 2005-110307

(51) Int. Cl. H03G 3/00

(52) U.S. Cl. 381/104; 381/107

(57) ABSTRACT

Apparatus and method to control the volume of a received sound, more particularly, an apparatus and method to control the volume of a received sound, which control the volume of sound data, converted into digital data, to a predetermined volume level using a software application. The apparatus includes a sound signal reception unit receiving analog sound signals, an Analog/Digital (A/D) conversion unit converting the analog sound signals into digital sound data, and a volume adjustment unit adjusting the volume of the digital sound data.

### CROSS-REFERENCE TO RELATED APPLICATION

This application claims the benefit of Korean Patent Application No. 2005-110307, filed on Nov. 17, 2005 in the Korean Intellectual Property Office, the disclosure of which is incorporated herein by reference.

### BACKGROUND OF THE INVENTION

1. Field of the Invention

Aspects of the present invention relate to an apparatus and method to control the volume of received sound signals and, more particularly, to an apparatus and method for controlling the volume of received sound signals, which convert analog sound signals input through a microphone into digital sound data, and adjust the volume of the digital sound data to a predetermined volume level using a software application.

2. Description of the Related Art

When external sound waves are input to a microphone, the microphone detects the input sound waves and generates analog signals. The generated analog signals are converted into digital data through an Analog/Digital (A/D) conversion device, such as an audio chip. The digital data may be stored in a storage device, such as memory or a hard disk, depending on the selection of a user.

The level of the input sound waves (that is, the volume) may be lower or higher than a predetermined critical value. In this case, an audio chip or a separate sound signal processing device can adjust the volume (the level of analog signals), and the sound signals having the adjusted volume can be converted into digital data. That is, the volume of input sound signals is adjusted using a hardware method.

Meanwhile, an apparatus (such as a telephone) which includes both a microphone and a speaker, delivers sound signals, input through the microphone, to a counter party via communication circuits, and simultaneously outputs sound signals through the speaker. In this case, when the volume of the input sound signals is higher than a predetermined critical value, the sound signals, having been output through the speaker, may be input through the microphone again. As a result, howling due to feedback may occur.

Therefore, the apparatus which includes both a microphone and a speaker has a limitation in that the volume of the sound signals, input through the microphone, must be maintained below a predetermined critical value. However, due to the limitation related to the volume of sound signals input through a microphone, the volume of the sound signals output through a speaker is also restricted.

Furthermore, sound data that has been converted into digital data generally has a volume lower than that of the original analog sound signals due to loss occurring when the analog sound signals are converted into the digital data. Therefore, when pieces of sound data, converted into digital data using different devices, are stored, the relative volumes thereof are different. As a result, there is an inconvenience in that a user must adjust the output volume of an apparatus for each piece of digital sound data when playing the digital sound data.

Korean Unexamined Patent Publication No. 1998-086034 discloses a method of automatically adjusting the volume of received sound signals according to a volume set by a listener using the MUSIC/SPEECH function of a Radio Data System (RDS). However, the patent, which is implemented additionally using a RES reception device that is hardware, does not resolve the above-described howling problem. Also, the manufacturing cost of a related apparatus may increase due to the addition of the hardware. Furthermore, when input sound signals are stored after conversion into digital data, the disclosed method has a disadvantage in that digital sound data is not stored in a state in which the relative volume is uniform. As a result, a method of controlling the volume of received sound signals using software is needed.

### SUMMARY OF THE INVENTION

Aspects of the present invention convert analog sound signals, input through a microphone, into digital data, and adjust the volume of the sound signals, converted into digital data, to a predetermined volume.

According to an aspect of the present invention, there is provided an apparatus to control the volume of received sound signals, the apparatus including a sound signal reception unit to receive analog sound signals, an Analog/Digital (A/D) conversion unit to convert the analog sound signals into digital sound data, and a volume adjustment unit to adjust the volume of the digital sound data.

According to another aspect of the present invention, there is provided a method of controlling the volume of received sound signals, the method including receiving analog sound signals, converting the analog sound signals into digital sound data, and adjusting the volume of the digital sound data.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a diagram illustrating an apparatus to control the volume of received sound signals according to an embodiment of the present invention;

FIG. 2 is a diagram illustrating a volume adjustment unit according to an embodiment of the present invention;

FIG. 3 is a diagram illustrating variation in the volume of digital sound data according to an embodiment of the present invention;

FIGS. 4A-4D are diagrams illustrating the division of digital sound data into predetermined sections according to an embodiment of the present invention;

FIGS. 5A-5C are diagrams illustrating the division of digital sound data into sections each having a size; and

FIG. 6 is a flowchart illustrating a process of controlling the volume of a sound on the basis of received sound signals according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

It is understood that each block and each operation of the flowchart illustrations, and combinations of blocks and operations in the flowchart illustrations, can be implemented by computer program instructions. These computer program instructions can be provided to a processor of a general purpose computer, special purpose computer, or other programmable data processing apparatus to produce a machine, such that the instructions, which execute via the processor of the computer or other programmable data processing apparatus, create devices to implement the functions specified in the flowchart block or blocks, or the flowchart operation or operations. These computer program instructions may also be stored in a computer-usable or computer-readable memory that can direct a computer or other programmable data processing apparatus to function in a particular manner, such that the instructions stored in the computer-usable or computer-readable memory produce an article of manufacture including instruction means that implement the function specified in the flowchart block or blocks or the flowchart operation or operations.

The computer program instructions may also be loaded onto a computer or other programmable data processing apparatus to cause a series of operational methods to be performed on the computer or other programmable apparatus to produce a computer-implemented process such that the instructions that execute on the computer or other programmable apparatus provide operations to implement the functions specified in the flowchart block or blocks or the flowchart operation or operations.

Further, each block of the flowchart illustrations may represent a module, segment, or portion of code, which includes one or more executable instructions to implement the specified logical function(s). It should also be noted that in some alternative implementations, the functions noted in the blocks and the operations may occur in a different order. For example, two blocks or two operations shown in succession may in fact be executed substantially concurrently, or the blocks and the operations may sometimes be executed in the reverse order, depending upon the functionality involved.

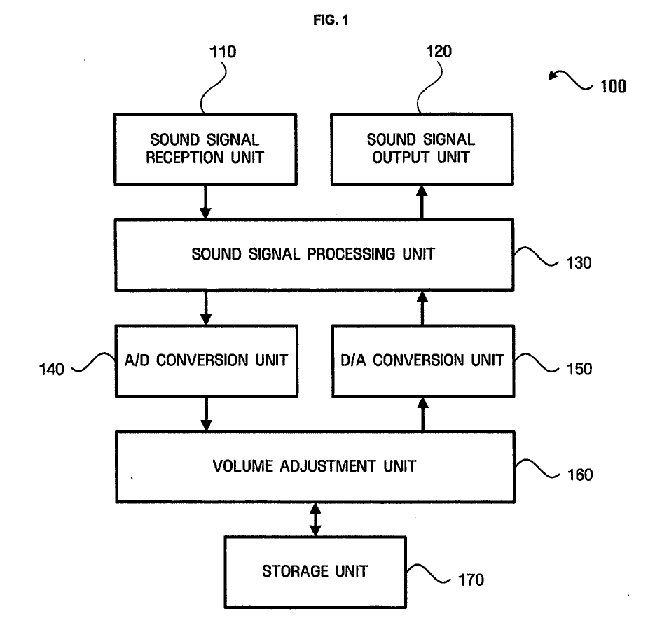

FIG. 1 is a block diagram illustrating an apparatus to control the volume of received sound signals 100 according to an embodiment of the present invention. The apparatus to control the volume of received sound signals (hereinafter referred to as a signal control apparatus) 100 includes a sound signal reception unit 110, a sound signal output unit 120, a sound signal processing unit 130, an A/D conversion unit 140, a Digital/Analog (D/A) conversion unit 150, a volume adjustment unit 160, and a storage unit 170. While not required in all aspects, the apparatus 100 can be used for Podcasting or included in a telephone, a computer using VOIP, or other communication devices.

The sound signal reception unit 110 functions to receive analog sound signals. That is, the sound signal reception unit functions to convert sound energy into electric energy. Generally, a microphone may act as the sound signal reception unit 110. The sound signal reception unit 110 converts sound signals into electric energy using any one of: an electric resistance change method of changing electric resistance using sound pressure; a piezo method of varying voltage using sound pressure based on a piezo effect; a magnetic field change method of generating voltage due to vibration of a thin metal plate, thereby varying a magnetic field; a dynamic method of locating an induction coil around a cylindrical magnet and using current generated in the coil by operating the coil as a vibration plate; and a condenser method of constructing a condenser by locating a vibration plate made of metal foil opposite a fixed electrode and varying the capacitance of the condenser while the vibration plate is moved by a sound; although not limited thereto.

The sound signal output unit 120 functions to output sound signals. That is, the sound signal output unit 120 converts electric signals containing sound information into the vibrations of a diaphragm, thereby generating waves of condensation and rarefaction toward air and, thus, radiating sound waves. Generally, a speaker performs the role of the sound signal output unit 120. The sound signal output unit 120 can convert electric signals into sound waves using any one of an electro-dynamic method, an electromagnetic method, an electrostatic method, a dielectric method, and a magnetic-distortion method, although not limited thereto. However, it is understood that the output unit 120 and/or reception unit 110 can be separately provided and connected to the apparatus 100 using wired and/or wireless connections.

Furthermore, the sound signal processing unit 130 can control the volume of sound signals delivered from the sound signal reception unit 110. Therefore, it is possible to adjust the volume of sound signals output through the sound signal output unit 120. However, it is understood that other aspects do not include the sound signal processing unit 130, and the volume is only controlled in the volume adjustment unit 160.

The A/D conversion unit 140 functions to convert analog sound signals into digital sound data. That is, the A/D conversion unit 140 performs digitization on the time axis and magnitude axis of the analog sound signals based on a predetermined sampling rate and bit rate. The sampling rate and the bit rate may vary depending on the setting of a user, or depending on the characteristics of sound signals input in real time.

The D/A conversion unit 150 functions to convert digital sound data into analog sound signals. In this case, the digital sound data which is input to the D/A conversion unit 150 may be digital sound data, the volume of which has been adjusted by the volume adjustment unit 160. As a result, the sound signal output unit 120 can output sound signals, the volume of which is uniform, regardless of the volume of sound signals input to the sound signal reception unit 110. However, it is understood that according to other aspects, the sound signal output unit 120 receives digital sound data to output. That is, the D/A conversion 150 unit may not be included in the apparatus 100 to the extent digital audio is reproduced at the output unit 120.

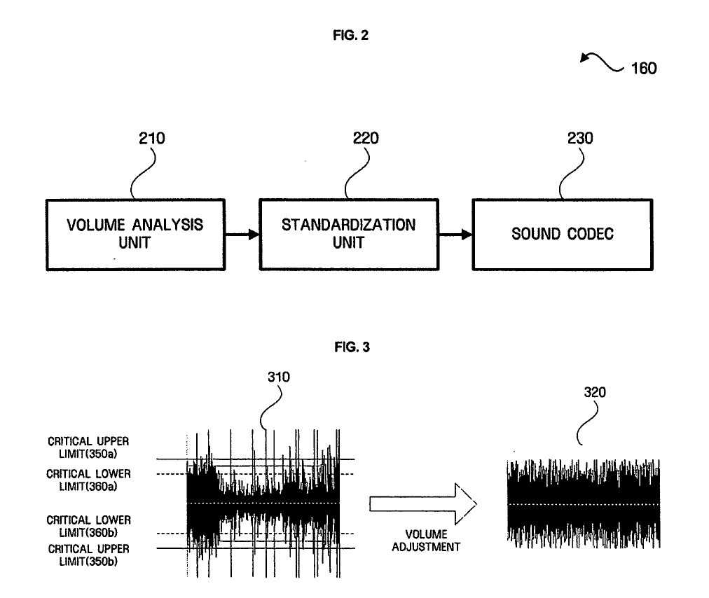

The volume adjustment unit 160 functions to adjust the volume of digital sound data. In this case, the volume adjustment unit 160 adjusts the volume of the digital sound data using a software application. The adjustment of the volume of the digital sound data may be performed based on a predetermined volume. That is, when the volume of the digital sound data, delivered from the A/D conversion unit 140, falls outside a predetermined range, the volume adjustment unit 160 adjusts the volume. When the volume of the digital sound data exceeds or falls below the upper limit or lower limit of the predetermined range, the volume adjustment unit 160 adjusts the volume such that the volume of the digital sound data falls within the predetermined range. A detailed description of the volume adjustment unit 160 is given with reference to FIG. 2. It is understood that the volume adjustment unit 160 may receive the digital sound data from the storage unit 170 or an external storage device, and not necessarily from the A/D conversion unit 140.

The storage unit 170 functions to store digital sound data, the volume of which is adjusted by the volume adjustment unit 160. The storage unit 170 is a module capable of inputting and outputting information, such as a hard disk, flash memory, a Compact Flash (CF) card, a Secure Digital (SD) card, a Smart Media (SM) card, a Multi-Media Card (MMC), or a memory stick, which can be embedded in the apparatus or be included in a separate apparatus. However, it is understood that in other aspects, the apparatus 100 may transmit and receive data through a wireless or wired connection with an external storage device.

FIG. 2 is a block diagram illustrating the volume adjustment unit 160 according to an embodiment of the present invention. The volume adjustment unit 160 includes a volume analysis unit 210, a standardization unit 220, and a sound codec 230. The volume analysis unit 210 functions to analyze whether the volume of digital sound data falls within a predetermined range. Thereafter, when the volume of the digital sound data falls outside the predetermined range, the volume analysis unit checks the difference between the volume of the digital sound data and the limits of the range.

Furthermore, when digital sound data is divided into predetermined sound data sections, the volume analysis unit 210 can analyze whether the volume of each of the digital sound data sections falls within a predetermined range. That is, the volume analysis unit 210 can analyze the volume of the entire digital sound data, which is delivered from the A/D conversion unit 140, and can also analyze the volumes of respective sound data sections.

In order to analyze the volumes of the sound data sections, though not required in all aspects, the sound signal control apparatus 100 may be equipped with buffers capable of storing digital sound data divided into the predetermined sound data sections, and a division unit to divide the digital sound data into sound data sections. The size of the sound data sections into which the digital sound data is divided can be determined by a user, or may vary depending on the characteristics of the digital sound data delivered in real time. For example, when the complexity (frequency) of the digital sound data is high, the size of the sound data sections may be set to a small value. When the complexity (frequency) of the digital sound data is low, the size of the sound data sections may be set to a large value.

Furthermore, the size of the sound data sections may be determined depending on variation in the volume of digital sound data. In order to examine whether each of the volumes of digital sound data sections falls within a predetermined critical range, the volume analysis unit 210 can use the average value of the volumes of the digital sound data sections. That is, the volume analysis unit 210 determines whether the average value of the volumes of the digital sound data sections falls within the critical range. When the average value falls outside the critical range, the difference between the average value and the critical range is delivered to the standardization unit 220.

The standardization unit 220 performs standardization such that the volume of the digital sound data falls within the critical range, based on the analysis result. That is, the standardization unit 220 amplifies the volume of the digital sound data to the lower limit of the critical range when the volume of the digital sound data is lower than the lower limit, and reduces the volume of the digital sound data to the upper limit of the critical range when the volume of the digital sound data is higher than the upper limit. In this case, the degree of amplification or reduction can be based on the difference between the average value and the critical range.

Furthermore, when the digital sound data is divided into sound data sections, the standardization unit 220 can perform standardization on the sound data sections having a volume which falls outside the predetermined range. That is, the standardization unit 220 can perform standardization on the volume of the entire digital sound data delivered from the volume analysis unit 210, or can perform standardization on the volumes of the sound data sections. The standardized digital sound data is delivered to the sound codec 230 or the D/A conversion unit 150.

The sound codec 230 functions to compress or decompress the standardized digital sound data. The compressed digital sound data is stored in the storage unit 170, or an external storage device.

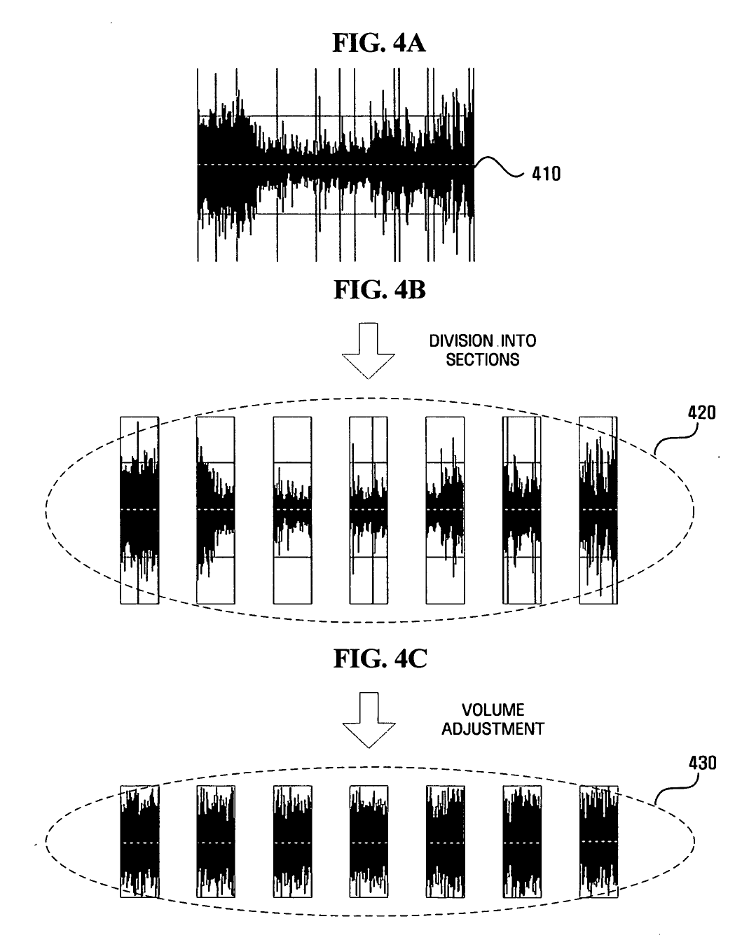

FIG. 3 is a diagram illustrating the adjustment of the volume of digital sound data according to an embodiment of the present invention. The volume of the digital sound data, converted by the A/D conversion unit 140, is adjusted by the volume adjustment unit 160. As illustrated in FIG. 3, the volume of the digital sound data 310 falls outside the upper limits 350a and 350b or lower limits 360a and 360b of the predetermined critical range. As a result, the volume adjustment unit 160 determines the difference between the volume of the digital sound data 310 and the upper limits 350a and 350b or lower limits 360a and 360b of the critical range, and generates digital sound data 320 having a standardized volume by amplifying or reducing the volume of the digital sound data 310 based on the difference.

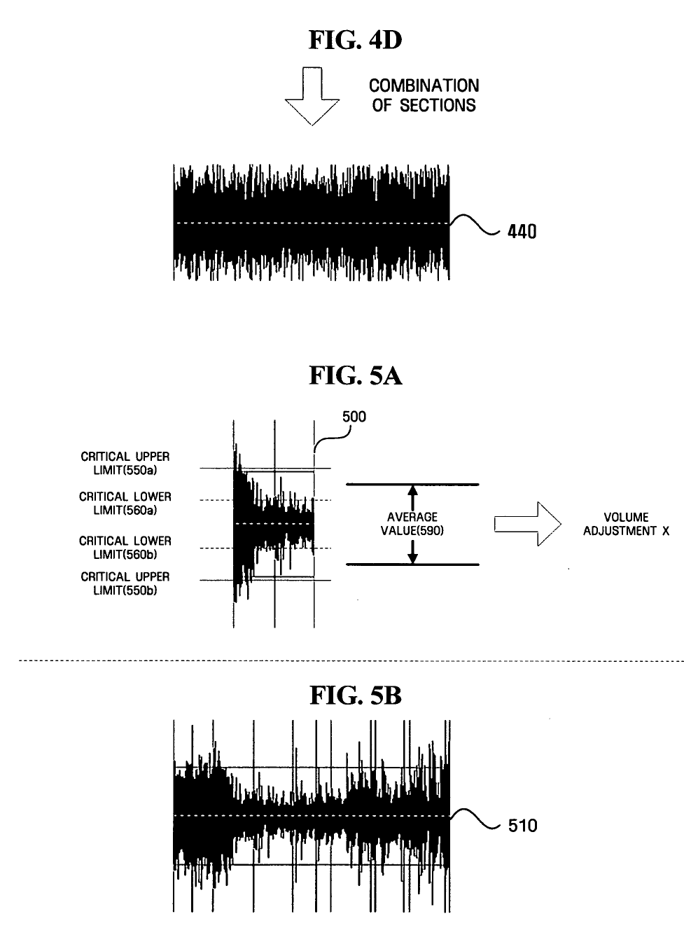

FIGS. 4A-4D are diagrams illustrating the division of digital sound data into predetermined sound data sections according to an embodiment of the present invention. Methods of performing volume adjustment on digital sound data can be classified into a method of determining whether the volume of entire digital sound data falls outside a predetermined critical range and then applying volume adjustment to the volume of the entire digital sound data based on the difference thereof, and a method of determining whether the volume of digital sound data falls outside a predetermined critical range and then applying volume adjustment to the volume of the digital sound data, based on the difference thereof, at regular time intervals.

Generally, the method of applying volume adjustment to the volume of entire digital sound data is not suitable for the adjustment of the volume of continuously input sound signals. Also, the method of adjusting the volume of digital sound data at regular time intervals may overload the sound signal control apparatus 100 through excessive operation. Therefore, the volume adjustment unit 160 generates digital sound data 420 in which digital sound data 410, converted by the A/D conversion unit 140, is divided into predetermined sound data sections, and performs volume adjustment on the respective sound data sections, thereby generating digital sound data 430 in which the volumes of the respective sound data of which have been adjusted. Furthermore, the respective sound data sections of digital sound data 430, the volumes of which have been adjusted, are combined with each other, thereby generating one piece of digital sound data 440, the volume of which is adjusted. However, it is understood that the other methods can be used in other aspects.

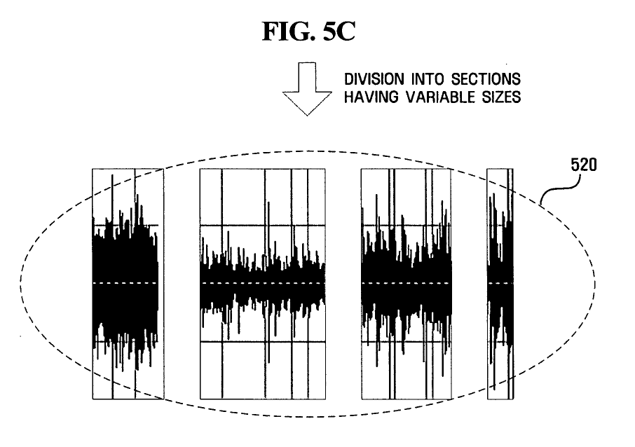

FIGS. 5A-5C are diagrams illustrating the division of digital sound data 510 into sound data sections 520, each having a variable size. The volume adjustment unit 160 or a division unit may, although not necessarily, divide input digital sound data 510 into sound data sections 500 having a fixed size. The size may be determined by a user. However, using the fixed size, the volume adjustment by the volume adjustment unit 160 may not be performed smoothly. By way of example, FIG. 5 illustrates the case in which digital sound data 500, the volume of which is above the upper limit of a predetermined critical range, and digital sound data 500, the volume of which is below the lower limit, are included in one section. In this case, the volume analysis unit 210 of the volume adjustment unit 160 calculates the average value 590 of the volumes of digital sound data 500 included in one sound data section, and then determines whether the average value 590 falls within the critical range. As a result, when pieces of digital sound data 500 which exceeds or falls below the upper limits 550a and 550b or lower limits 560a and 560b of the critical range are included in one section, the average value 590 of the section may fall within the critical range. Therefore, the volume analysis unit 210 considers that there is no difference between the average value 590 of respective sound data sections and the critical range, so the standardization unit 550 does not perform the standardization of volume.

In order to prevent the above problem, the volume adjustment unit 160 can divide the input digital sound data 510 into sections having variable sizes, rather than a fixed size. That is, the volume adjustment unit 160 generates digital sound data 520 that is divided into digital sound data sections of variable sizes, each having similar volume levels. As a result, the average value of each of the sound data sections can be taken as the average value of the volumes of each of the digital sound data sections, and thus the error of the volume adjustment can be reduced.

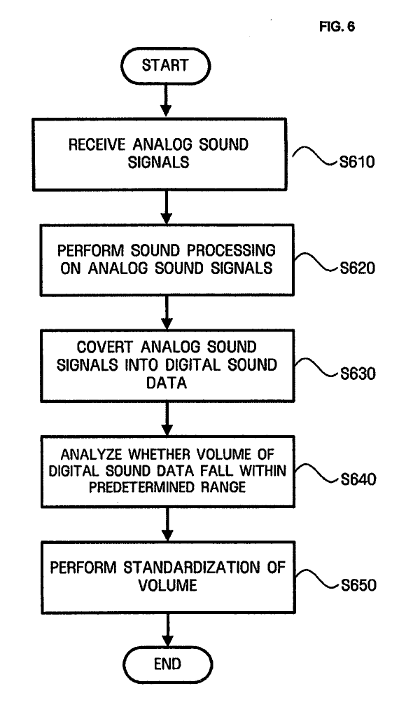

FIG. 6 is a flowchart illustrating a process of controlling the volume of received sound signals according to an embodiment of the present invention. In order to control the volume of the received sound signals, the sound signal reception unit 110 of the sound signal control apparatus 100 receives analog sound signals at operation S610. The sound energy of the received sound signals is converted into electrical energy, and is then delivered to the sound signal processing unit 130.

The sound signal processing unit 130 performs sound processing on the analog sound signals having an electric energy form at operation S620. In this case, the sound processing may include noise elimination, sound signal amplification, and volume adjustment. The sound signals on which sound processing has been performed is output through the sound signal output unit 120 or is delivered to the A/D conversion unit 140.

The A/D conversion unit 140 converts the delivered analog sound signals into digital sound data at operation S630. That is, the A/D conversion unit 140 performs digitization on the time axis and magnitude axis of the analog sound signals according to a predetermined sampling rate and bit rate.

The digital sound data digitized by the A/D conversion unit 140 is delivered to the volume adjustment unit 160. The volume analysis unit 210 of the volume adjustment unit 160 analyzes whether the volume of the delivered digital sound data falls within a predetermined critical range at operation S640. The volume analysis may be performed by analyzing the difference between the average value of the delivered digital sound data and the upper limit or lower limit of the critical range.

Meanwhile, the volume analysis unit 210 may analyze the volumes of digital sound data sections into which sound data is divided based on a predetermined volume level. In this case, the digital sound data sections may be a series of digital sound data having similar volumes. That is, digital sound data, converted by the A/D conversion unit 140, can be divided at points at which variation in volume is large and which are used as the borders of the sound data sections.

The analysis result of the volume analysis unit 210 (that is, the difference between the average value and the critical range) is delivered to the standardization unit 220. The standardization unit 220 performs volume standardization on digital sound data based on the delivered difference at operation S650. The digital sound signal on which the standardization has been performed may be stored in the storage unit 170 or delivered to the D/A conversion unit 150.

Furthermore, predetermined sound processing is performed by the sound signal processing unit 130 on the analog sound signals, which are converted by the D/A conversion unit 150 and are then output via the sound signal output unit 120.

The apparatus and method to control the volume of received sound signals of the present invention provides one or more following advantages. There is an advantage of generating data having a uniform volume regardless of the volume of sound signals input through a microphone by adjusting the volume of a sound converted into digital sound data to a predetermined volume. There is also the advantage of reducing the manufacturing cost by controlling the volume of sound data using a software application.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An apparatus to control a volume of received sound signals, the apparatus comprising:
a sound signal reception unit to receive analog sound signals;
an Analog/Digital (A/D) conversion unit to convert the analog sound signals into digital sound data; and
a volume adjustment unit to adjust a volume of the digital sound data.

2. The apparatus as claimed in claim 1, wherein the volume adjustment unit adjusts the volume of the digital sound data using a software application.

3. The apparatus as claimed in claim 1, wherein the volume adjustment unit adjusts the volume of the digital sound data to a predetermined volume.

4. The apparatus as claimed in claim 1, wherein the volume adjustment unit comprises:
a volume analysis unit to analyze whether the volume of the digital sound data is within a predetermined range; and
a standardization unit to perform standardization based on an analysis result of the volume analysis unit such that the volume of the digital sound data is within the range.

5. The apparatus as claimed in claim 4, wherein when the volume of the digital sound data is outside the predetermined range, the volume analysis unit calculates a difference between the volume of the digital sound data and a limit of the predetermined range and transmits the difference to the standardization unit to adjust the volume to be within the limit.

6. The apparatus as claimed in claim 4, further comprising a division unit to divide the digital sound data into a plurality of sound data sections comprising a first sound data section, having a volume that is outside the predetermined range, and/or a second sound data section, having no volume that is outside the predetermined range, wherein the volume analysis unit analyzes whether a volume of each of the plurality of sound data sections is within the predetermined range, and the standardization unit performs standardization on the first sound data section.

7. The apparatus as claimed in claim 6, wherein the volume analysis unit determines whether an average value of volumes within each of the plurality of sound data sections is within the predetermined range.

8. The apparatus as claimed in claim 6, wherein the apparatus combines the plurality of sound data sections after the standardization unit performs standardization.

9. The apparatus as claimed in claim 6, wherein the division unit divides the digital sound data into the plurality of sound data sections having sizes determined by a user.

10. The apparatus as claimed in claim 6, wherein the division unit divides the digital sound data into the plurality of sound data sections having variable sizes.

11. The apparatus as claimed in claim 7, wherein the division unit divides the digital sound data into the plurality of sound data sections having variable sizes, each having similar volume levels such that the average value of the volumes of the first sound data section is outside the predetermined range, and the average value of the volumes of the second sound data section is within the predetermined range.

12. The apparatus as claimed in claim 4, wherein the digital sound data comprises a plurality of sound data sections comprising a first sound data section, having a volume that is outside the predetermined range, and/or a second sound data section, having no volume that is outside the predetermined range, and the standardization unit performs standardization on the first sound data section.

13. The apparatus as claimed in claim 12, wherein the apparatus combines the plurality of sound data sections after the standardization unit performs standardization.

14. The apparatus as claimed in claim 1, wherein the sound signal reception unit is a microphone.

15. The apparatus as claimed in claim 1, further comprising:
a Digital/Analog (D/A) conversion unit to convert the digital sound data into analog sound signals after the volume of the digital sound data is adjusted;
a sound signal output unit to output the analog sound signals converted by the D/A conversion unit; and
a storage unit to store the digital sound data after the volume of the digital sound data is adjusted.

16. A method of controlling a volume of received sound signals, the method comprising:
receiving analog sound signals;
converting the analog sound signals into digital sound data; and
adjusting the volume of the digital sound data.

17. The method as claimed in claim 16, wherein the adjusting the volume comprises adjusting the volume of the digital sound data using a software application.

18. The method as claimed in claim 16, wherein the adjusting of the volume comprises adjusting the volume of the digital sound data to a predetermined volume.

19. The method as claimed in claim 16, wherein the adjusting the volume comprises:
analyzing whether the volume of the digital sound data is within a predetermined range; and
performing standardization based on an analysis result such that the volume of the digital sound data is within the range.

20. The method as claimed in claim 19, wherein the analyzing comprises:
calculating a difference between the volume of the digital sound data and a limit of the predetermined range.

21. The method as claimed in claim 19, wherein the adjusting of the volume further comprises dividing the digital sound data into a plurality of sound data sections comprising a first sound data section, having a volume that is outside the predetermined range, and/or a second sound data section, having no volume that is outside the predetermined range, such that the analyzing comprises analyzing whether a volume of each of the plurality of sound data sections is within the predetermined range, and the performing of standardization comprises performing standardization on the first sound data section.

22. The method as claimed in claim 21, wherein the analyzing further comprises determining whether an average value of volumes within each of the plurality of sound data sections falls within the predetermined range.

23. The method as claimed in claim 21, further comprising combing the plurality of sound data sections after the performing of standardization.

24. The method as claimed in claim 21, wherein the dividing of the digital sound data comprises dividing the digital sound data into the plurality of sound data sections having variable sizes.

25. The method as claimed in claim 22, wherein the dividing of the digital sound data comprises dividing the digital sound data into the plurality of sound data sections having variable sizes, each having similar volume levels such that the average value of the volumes of the first sound data section is outside the predetermined range, and the average value of the volumes of the second sound data section is within the predetermined range.

26. The method as claimed in claim 19, wherein the digital sound data comprises a plurality of sound data sections comprising a first sound data section, having a volume that is outside the predetermined range, and/or a second sound data section, having no volume that is outside the predetermined range, and the performing of standardization comprises performing standardization on the first sound data section.

27. The method as claimed in claim 16, further comprising:
converting the adjusted digital sound data into analog sound signals; and
outputting the converted analog sound signals.

28. The method as claimed in claim 16, further comprising:
storing the adjusted digital sound data.

29. An apparatus to control a volume of received sound signals, the apparatus comprising:
a volume analysis unit to analyze whether the volume of digital sound data is within a predetermined range after the digital sound data is converted from received analog sound signals; and
a standardization unit to perform standardization based on an analysis result of the volume analysis unit such that the volume of the digital sound data is within the range.

30. The apparatus as claimed in claim 29, wherein when the volume of the digital sound data is outside the predetermined range, the volume analysis unit calculates a difference between the volume of the digital sound data and a limit of the predetermined range and transmits the difference to the standardization unit.

31. The apparatus as claimed in claim 29, further comprising a division unit to divide the digital sound data into a plurality of sound data sections comprising a first sound data section, having a volume that is outside the predetermined range, and/or a second sound data section, having no volume that is outside the predetermined range, wherein the volume analysis unit analyzes whether a volume of each of the plurality of sound data sections is within the predetermined range, and the standardization unit performs standardization on the first sound data section.

32. The apparatus as claimed in claim 31, wherein the volume analysis unit determines whether an average value of volumes within each of the plurality of sound data sections is within the predetermined range.

33. The apparatus as claimed in claim 31, wherein the apparatus combines the plurality of sound data sections after the standardization unit performs standardization.

34. The apparatus as claimed in claim 31, wherein the division unit divides the digital sound data into the plurality of sound data sections having variable sizes.

35. The apparatus as claimed in claim 32, wherein the division unit divides the digital sound data into the plurality of sound data sections having variable sizes, each having similar volume levels such that the average value of the volumes of the first sound data section is outside the predetermined range, and the average value of the volumes of the second sound data section is within the predetermined range.

36. A method of controlling a volume of received sound signals, the method comprising:
analyzing whether the volume of digital sound data, after conversion from analog sound signals, is within a predetermined range; and
performing standardization based on an analysis result such that the volume of the digital sound data is within the range.

37. The method as claimed in claim 36, wherein the analyzing comprises:
calculating a difference between the volume of the digital sound data and a limit of the predetermined range.

38. The method as claimed in claim 36, further comprising dividing the digital sound data into a plurality of sound data sections comprising a first sound data section, having a volume that is outside the predetermined range, and/or a second sound data section, having no volume that is outside the predetermined range, such that the analyzing comprises analyzing whether a volume of each of the plurality of sound data sections is within the predetermined range, and the performing of standardization comprises performing standardization on the first sound data section.

39. The method as claimed in claim 38, wherein the analyzing further comprises determining whether an average value of volumes within each of the plurality of sound data sections falls within the predetermined range.

40. The method as claimed in claim 38, further comprising combing the plurality of sound data sections after the performing of standardization.

41. The method as claimed in claim 38, wherein the dividing of the digital sound data comprises dividing the digital sound data into the plurality of sound data sections having variable sizes.

42. The method as claimed in claim 39, wherein the dividing of the digital sound data comprises dividing the digital sound data into the plurality of sound data sections having variable sizes, each having similar volume levels such that the average value of the volumes of the first sound data section is outside the predetermined range, and the average value of the volumes of the second sound data section is within the predetermined range.

43. A computer readable recording medium encoded with the method of claim 36 implemented by a computer.
